(19) United States
(12) Patent Application Publication
(10) Pub. No.: US 2025/0338550 A1
(43) Pub. Date: Oct. 30, 2025

(54) SEMICONDUCTOR DEVICE INCLUDING A SiC SEMICONDUCTOR BODY

(71) Applicant: Infineon Technologies AG, Neubiberg (DE)

(72) Inventors: Thomas Aichinger, Faak am See (AT); Michael Hell, Erlangen (DE); Wolfgang Bergner, Klagenfurt am Wörthersee (AT)

(21) Appl. No.: 19/173,379

(22) Filed: Apr. 8, 2025

(30) Foreign Application Priority Data
Apr. 25, 2024 (DE) 102024203909.8

(51) Int. Cl. H10D 30/66; H10D 12/00; H10D 12/01; H10D 30/01; H10D 62/10; H10D 62/13; H10D 62/17; H10D 62/60; H10D 62/832

(52) U.S. Cl. CPC H10D 30/668; H10D 12/038; H10D 12/481; H10D 30/0297; H10D 62/124; H10D 62/155; H10D 62/235; H10D 62/60; H10D 62/8325

(57) ABSTRACT

A semiconductor device includes a SiC semiconductor body having a mesa between trench gate structures, with a one-sided channel region adjoining a first mesa sidewall of opposite first and second mesa sidewalls. A first conductivity type region adjoins the first mesa sidewall and a top surface of the mesa. A second conductivity type region adjoins the second mesa sidewall and the top surface, with a pn junction separating the first and second regions at the top surface. A width of the first region at the top surface alternates, along a longitudinal direction of the mesa, between first and second width ranges. The first width range is larger than 10% and smaller than 50% of the mesa width at the top surface. The second width range is larger than or equal to 50% and smaller than 90% of the mesa width at the top surface.

### TECHNICAL FIELD

The present disclosure is related to a semiconductor device, in particular to semiconductor device including a SiC semiconductor body.

### BACKGROUND

Technology development of new generations of SiC semiconductor devices, e.g. insulated gate field effect transistors (IGFETs) such as metal oxide semiconductor field effect transistors (MOSFETs) or insulated gate bipolar transistors (IGBTs), aims at improving electrical device characteristics and reducing costs by shrinking device geometries. Although costs may be reduced by shrinking device geometries, a variety of tradeoffs and challenges have to be met when increasing device functionalities per unit area. For example, reducing the area-specific on-state resistance, RₒₙxA, may be challenging in view of process-related variations when arranging trenches relative to doped regions or doped regions relative to one another. Such process-related variations may be caused by process technology including different lithographic levels. For example, formation of contacts, e.g. contact plugs or contact lines or vias, on mesa regions may become challenging when shrinking the width of the mesa for reducing the area-specific on-state resistance, RₒₙxA.

There is a need for improving electric contacts on mesa regions when shrinking device geometries.

### SUMMARY

An example of the present disclosure relates to a semiconductor device including a SiC semiconductor body. The SiC semiconductor body includes a mesa between trench gate structures. The mesa includes a one-sided channel region. The one-sided channel region adjoins a first mesa sidewall of opposite first and second mesa sidewalls. The mesa further includes a first region of a first conductivity type adjoining the first mesa sidewall and a top surface of the mesa. The mesa further includes a second region of a second conductivity type adjoining the second mesa sidewall and the top surface of the mesa. The first region and the second region are separated by a pn junction at the top surface of the mesa. A width of the first region at the top surface of the mesa alternates, along a longitudinal direction of the mesa, between a first width range and a second width range. The first width range is larger than 10% of a width of the mesa at the top surface and smaller than 50% of the width of the mesa at the top surface. The second width range is larger than or equal to 50% of the width of the mesa at the top surface and smaller than 90% of the width of the mesa at the top surface.

Another example of the present disclosure relates to a semiconductor device including a SiC semiconductor body. The SiC semiconductor body includes a mesa between trench gate structures. The mesa includes a one-sided channel region. The one-sided channel region adjoins a first mesa sidewall of opposite first and second mesa sidewalls. The mesa further includes first transverse regions of a first conductivity type adjoining the top surface of the mesa. The first transverse regions extend from the first mesa sidewall to the second mesa sidewall. The mesa further includes second transverse regions of a second conductivity type adjoining the top surface of the mesa. The second transverse regions extend from the first mesa sidewall to the second mesa sidewall. The first transverse regions and the second transverse regions are alternately arranged along a longitudinal direction of the mesa.

Another example of the present disclosure relates to a method of manufacturing a semiconductor device. The method includes forming trench gate structures in a SiC semiconductor body. A mesa is arranged between the trench gate structures. The method further includes forming a one-sided channel region in the mesa. The one-sided channel region adjoins a first mesa sidewall of opposite first and second mesa sidewalls. The method further includes forming a first region of a first conductivity type in the mesa. The first region adjoins the first mesa sidewall and a top surface of the mesa. The method further includes forming a second region of a second conductivity type in the mesa. The second region adjoins the second mesa sidewall and the top surface of the mesa. The first region and the second region are separated by a pn junction at the top surface of the mesa. A width of the first region at the top surface of the mesa alternates, along a longitudinal direction of the mesa, between a first width range and a second width range. The first width range is larger than 10% of a width of the mesa at the top surface and smaller than 50% of the width of the mesa at the top surface. The second width range is larger than or equal to 50% of the width of the mesa at the top surface and smaller than 90% of the width of the mesa at the top surface.

Another example of the present disclosure relates to a method of manufacturing a semiconductor device. The method includes forming trench gate structures in a SiC semiconductor body. A mesa is arranged between the trench gate structures. The method further includes forming a one-sided channel region in the mesa. The one-sided channel region adjoins a first mesa sidewall of opposite first and second mesa sidewalls. The method further includes forming first transverse regions of a first conductivity type adjoining the top surface of the mesa. The first transverse regions extend from the first mesa sidewall to the second mesa sidewall. The method further includes forming second transverse regions of a second conductivity type adjoining the top surface of the mesa. The second transverse regions extend from the first mesa sidewall to the second mesa sidewall. The first transverse regions and the second transverse regions are alternately arranged along a longitudinal direction of the mesa.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the embodiments and are incorporated in and constitute a part of this specification. The drawings illustrate embodiments of semiconductor devices and methods of manufacturing semiconductor devices and together with the description serve to explain principles of the embodiments. Further embodiments are described in the following detailed description and the claims.

FIGS. 1 and 2 are exemplary process illustrations of manufacturing a semiconductor device.

FIGS. 3A to 3D schematically and exemplarily illustrate top views on a semiconductor device including a mesa laterally confined by trench gate structures.

FIGS. 4A and 4B are cross-sectional views for illustrating exemplary layouts taken along lines AA′ and BB′ of the semiconductor devices illustrated in the top views of FIGS. 3A to 3D.

FIG. 5 schematically and exemplarily illustrates a top view on a semiconductor device including a mesa laterally confined by trench gate structures.

FIGS. 6A and 6B are cross-sectional views for illustrating exemplary layouts taken along lines AA′ and BB′ of the semiconductor device illustrated in the top view of FIG. 5.

FIG. 7 schematically and exemplarily illustrates a top view on a semiconductor device including a mesa laterally confined by trench gate structures.

FIGS. 8A and 8B are cross-sectional views for illustrating exemplary layouts taken along lines AA′ and BB′ of the semiconductor device illustrated in the top view of FIG. 7.

### DETAILED DESCRIPTION

In the following detailed description, reference is made to the accompanying drawings, which form a part hereof and in which are shown by way of illustrations specific examples in which semiconductor substrates may be processed. It is to be understood that other examples may be utilized and structural or logical changes may be made without departing from the scope of the present disclosure. For example, features illustrated or described for one example can be used on or in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” may describe a permanent low-resistive connection between electrically connected elements, for example a direct contact between the concerned elements or a low-resistive connection via a metal and/or heavily doped semiconductor material. The term “electrically coupled” may include that one or more intervening element(s) adapted for signal and/or power transmission may be connected between the electrically coupled elements, for example, elements that are controllable to temporarily provide a low-resistive connection in a first state and a high-resistive electric decoupling in a second state.

If two elements A and B are combined using an “or”, this is to be understood to disclose all possible combinations, i.e. only A, only B as well as A and B, if not explicitly or implicitly defined otherwise. An alternative wording for the same combinations is “at least one of A and B” or “A and/or B”. The same applies, mutatis mutandis, for combinations of more than two elements.

Ranges given for physical dimensions include the boundary values. For example, a range for a parameter y from a to b reads as a≤y≤b. The same holds for ranges with one boundary value like “at most” and “at least”.

Main constituents of a layer or a structure from a chemical compound or alloy are such elements which atoms form the chemical compound or alloy. For example, silicon (Si) and carbon (C) are the main constituents of a silicon carbide (SiC) layer.

The term “on” is not to be construed as meaning only “directly on”. Rather, if one element is positioned “on” another element (e.g., a layer is “on” another layer or “on” a substrate), a further component (e.g., a further layer) may be positioned between the two elements (e.g., a further layer may be positioned between a layer and a substrate if the layer is “on” said substrate).

The description and drawings merely illustrate the principles of the disclosure. Furthermore, all examples recited herein are principally intended expressly to be only for illustrative purpose to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

A configuration example of a semiconductor device includes a SiC semiconductor body. The SiC semiconductor body includes a mesa between trench gate structures.

The mesa includes a one-sided channel region. The one-sided channel region adjoins a first mesa sidewall of opposite first and second mesa sidewalls.

The mesa further includes a first region of a first conductivity type adjoining the first mesa sidewall and to a top surface of the mesa. The mesa further includes a second region of a second conductivity type adjoining to the second mesa sidewall and to the top surface of the mesa. The first region and the second region are separated by a pn junction at the top surface of the mesa.

A width of the first region at the top surface of the mesa may alternate, along a longitudinal direction of the mesa, between a first width range and a second width range, the first width range being larger than 10% of a width of the mesa at the top surface and may be smaller than 50% of the width of the mesa at the top surface. The second width range may be larger than or equal to 50% of the width of the mesa at the top surface and may be smaller than 90% of the width of the mesa at the top surface. A minimum width of the first region may thus be in the first width range, and a maximum width of the first region may thus be in the second width range. Likewise, a minimum width of the second region thus be in the first width range, and a maximum width of the second region may thus be in the second width range. At a predefined position along the longitudinal direction, a sum of the widths of the first and second regions may correspond to the width of the mesa. For example, a difference between the minimum width of the first region and the maximum width of the first region may be in a range from 20% to 80%, or from 30% to 70%, or from 40% to 60% of the width of the mesa.

The semiconductor device may be part of an integrated circuit or may be a discrete semiconductor device or a semiconductor module, for example. The semiconductor device may be or may include an insulated gate field effect transistor (IGFET) such as a metal oxide semiconductor field effect transistor (MOSFET) or an insulated gate bipolar transistor (IGBT), for example. The semiconductor device may be a vertical semiconductor device having a load current flow between the first surface and a second surface opposite to the first surface along a vertical direction. The vertical power semiconductor device may be configured to conduct currents of more than 1 A, or more than 10 A, or more than 30 A, or more than 50 A, or more than 75 A, or even more than 100 A, and may be further configured to block voltages between load electrodes, e.g. between collector and emitter on an IGBT, or between drain and source of a MOSFET, in the range of several hundreds of up to several thousands of volts, e.g. 400 V, 650 V, 1.2 kV, 1.7 kV, 3.3 kV, 4.5 kV, 5.5 kV, 6 kV, 6.5 kV, 10 kV. The blocking voltage may correspond to a voltage class specified in a datasheet of the power semiconductor device, for example.

The semiconductor device may be based on a SiC semiconductor body from a crystalline SiC material. The crystalline SiC material may have a hexagonal crystal lattice, by way of example. For example, the semiconductor material may be 2H-SiC (SiC of the 2H polytype), 6H-SiC or 15R-SiC. According to an example, the semiconductor material is silicon carbide of the 4H polytype (4H-SiC). The SiC semiconductor body may include or consist of a semiconductor substrate having none, one or more than one semiconductor layers, e.g. epitaxially grown layers, thereon. One of the semiconductor layers may be a doped semiconductor layer of a current spread layer, for example.

The top surface of the mesa may define a front surface or a top surface of the SiC semiconductor body, and the SiC semiconductor body may further have a second surface that may be a back surface or a rear surface of the SiC semiconductor body, for example. The SiC semiconductor body may be attached to a lead frame via the second surface, for example. Over the first surface of the SiC semiconductor body, bond pads may be arranged and bond wires may be bonded on the bond pads, for example.

For realizing a desired current carrying capacity, the SiC semiconductor device may be designed by a plurality of parallel-connected SiC semiconductor device cells. The parallel-connected SiC semiconductor device cells may, for example, be SiC semiconductor device cells formed in the shape of a strip or a strip segment. Of course, the SiC semiconductor device cells can also have any other shape, e.g. circular, elliptical, polygonal such as hexagonal or octahedral. The semiconductor device cells may be arranged in a transistor cell area of the SiC semiconductor body. The transistor cell area may be an area where an emitter region of an IGBT (or a source region of a MOSFET) and a collector region of an IGBT (or a drain region of a MOSFET) are arranged opposite to one another along a vertical direction. In the transistor cell area, a load current may enter or exit the SiC semiconductor body of the semiconductor device, e.g. via contact plugs or contact lines on the top surface of the mesa. The semiconductor device may further include an edge termination area that may include a termination structure. In a blocking mode or in a reverse biased mode of the semiconductor device, the blocking voltage between the transistor cell area and a field-free region laterally drops across the termination structure. The termination structure may have a higher or a slightly lower voltage blocking capability than the transistor cell area. The termination structure may include a junction termination extension (JTE) with or without a variation of lateral doping (VLD), one or more laterally separated guard rings, or any combination thereof, for example.

For example, the mesa may be laterally confined, e.g. along a second lateral direction, by trench gate structures. The longitudinal direction of the mesa may be a first lateral direction that extends perpendicular to the second lateral direction. The longitudinal direction of the mesa and the second lateral direction may be perpendicular to the vertical direction. The trench gate structures may each include a gate dielectric and a gate electrode, for example.

An electric contact on the top surface of the mesa, e.g. a line-shaped contact extending along the longitudinal direction, may directly contact the first region and the second region on the top surface of the mesa. By varying the width of the first region at the top surface and, inverse thereto, the width of the second region at the top surface along the longitudinal direction of the mesa and within the width ranges described herein, a negative impact of degraded contact resistance or critically small contact widths caused by shrinking of device geometries, e.g. mesa width, may be counteracted. This may allow to improve a the RₒₙxA when shrinking device geometries. Moreover, improvement of the contact resistance for n- and p-regions at the top surface of the mesa further allows to stabilize the n- and p-regions on source or emitter potential. This may allow for improving the switching behavior of the device.

For example, the first region may be a source region. The second region may be a contact region. A first depth from a bottom side of the contact region to the top surface of the mesa may be larger than a second depth from a bottom side of the source region to the top surface of the mesa.

For example, the second region may be part of a continuous region of the second conductivity type. The continuous region may adjoin to the second mesa sidewall and to a bottom side of a trench gate structure. A vertical doping concentration profile of the continuous region may include a plurality of doping concentration profiles of doped regions that partially overlap along a vertical direction, for example. A bottom portion of the continuous region may be configured to shield a gate dielectric of a trench gate structure from high electric fields. For example, the bottom portion of the continuous region may laterally adjoin a current spread region of the first conductivity type. The current spread region may have a larger doping concentration than a drift region. The drift region may adjoin a bottom side of the current spread region, for example.

For example, the continuous region may completely cover or line the second sidewall from the bottom side of the trench gate structure to the top surface of the mesa.

For example, the semiconductor device may further include a body region of the second conductivity type. The body region may be laterally arranged between the continuous region and the first mesa sidewall. The body region may adjoin the first sidewall of the mesa. A portion of the body region adjoining the first sidewall may define the one-sided channel region. For example, the contact or second region may vertically end in the body region, e.g. at least with respect to cross-sectional views taken along a longitudinal direction of the mesa where the contact or second region has a larger width than the first or source region.

For example, the semiconductor device may further include a buried third region of the first conductivity type. The buried third region may adjoin a bottom side of the first region and may allow for a reduction of the path resistance of a channel current from the one-sided channel region to the contact on the top surface of the mesa in those segments along the mesa region where on the top surface part the contact or second region is wider than the source or first region, for example.

For example, a maximum doping concentration of the first region may be by at least one order of magnitude larger than a maximum doping concentration of the buried third region.

For example, in a top view on the top surface of the mesa, a shape of the first region along the longitudinal direction may be at least one of a sine wave, or a square wave, or a triangle wave, or a sawtooth wave. Other shapes having minimum and maximum widths alternating between the first and second width ranges, respectively, may as well allow for the technical benefits described herein.

For example, the first region may be an n⁺⁺-doped source region. A surface coverage of the top surface of the mesa by the second region may be by more than 10% larger than a surface coverage of the top surface of the mesa by the first region. This may be beneficial when electrical contact properties of n- and p-doped regions differ from one another.

For example, the first region may be an n⁺⁺-doped source region. A surface coverage of the top surface of the mesa by the second region may be equal to a surface coverage of the top surface of the mesa by the first region. This may allow for maximizing electric contact surface shares of both n- and p-doped regions, for example.

Details with respect to structure, or function, or technical benefit of features described above with respect to a semiconductor device, e.g. such as a FET, or IGBT, likewise apply to the examples of semiconductor devices described further below.

A further configuration example relates to a semiconductor device including a SiC semiconductor body. The SiC semiconductor body includes a mesa between trench gate structures. The mesa includes a one-sided channel region. The one-sided channel region adjoins a first mesa sidewall of opposite first and second mesa sidewalls. The SiC semiconductor body further includes first transverse regions of a first conductivity type adjoining the top surface of the mesa. The first transverse regions may extend from the first mesa sidewall to the second mesa sidewall. The SiC semiconductor body further includes second transverse regions of a second conductivity type adjoining the top surface of the mesa. The second transverse regions may extend from the first mesa sidewall to the second mesa sidewall. The first transverse regions and the second transverse regions may be alternately arranged along a longitudinal direction of the mesa.

An electric contact on the top surface of the mesa, e.g. a line-shaped contact extending along the longitudinal direction, may directly contact the first transverse region and the second transverse region on the top surface. By alternatingly arranging the first and second transverse regions, the electric contact at a predefined position along the longitudinal direction either provides an electric contact on the first transverse region or on the second transverse region. A negative impact of degraded contact resistance or critically small contact widths caused by shrinking of device geometries and by electrically contacting both the source region and the body region at a predefined position along the longitudinal direction may be counteracted. This may allow for improving the RₒₙxA when shrinking device geometries.

For example, the semiconductor device may further include a buried interconnection region of the first conductivity type. The buried interconnection region may extend along the longitudinal direction and may electrically connect the first transverse regions with one another. For example, the buried interconnection region may adjoin a bottom side of the second transverse regions.

For example, a maximum doping concentration of the first transverse regions may be by at least one order of magnitude larger than a maximum doping concentration of the buried interconnection region.

For example, the second transverse regions may be part of a continuous region of the second conductivity type. The continuous region may adjoin to the second mesa sidewall and a bottom side of a trench gate structure. A vertical doping concentration profile of the continuous region may include a plurality of doping concentration profiles of doped regions that partially overlap along the vertical direction, for example. A bottom portion of the continuous region may be configured to shield a gate dielectric of a trench gate structure from high electric fields. For example, the bottom portion of the continuous region may laterally adjoin a current spread region of the first conductivity type. The current spread region may have a larger doping concentration than a drift region adjoining a bottom side of the current spread region, for example.

For example, the semiconductor device may further include a line-shape contact on the top surface of the mesa. For some examples described herein, the line shape-contact may extend along the longitudinal direction and may directly contact the alternately arranged first and second transverse regions at different positions along the longitudinal direction, for example. Likewise, for some further examples described herein, the line shape-contact may extend along the longitudinal direction and may directly contact each of the first and second regions at a predefined position along the longitudinal direction, wherein a contact surface share of p- and n-doped regions alternates along the longitudinal direction, for example.

Details with respect to structure, or function, or technical benefit of features described above with respect to a semiconductor device such as a FET, or IGBT likewise apply to the exemplary methods described further below. Processing the SiC semiconductor body may comprise one or more optional additional features corresponding to one or more aspects mentioned in connection with the proposed concept or one or more examples described above or below.

Some of the above and below examples are described in connection with a silicon carbide substrate. Alternatively, a wide band gap semiconductor substrate, e.g. a wide band gap wafer, may be processed, e.g. comprising a wide band gap semiconductor material different from silicon carbide. The wide band gap semiconductor wafer may have a band gap larger than the band gap of silicon (1.12 eV). For example, the wide band gap semiconductor wafer may be a silicon carbide (SiC) wafer, or gallium arsenide (GaAs) wafer. In some further examples, a silicon semiconductor substrate may be processed.

In some of the illustrated examples, n-channel FETs or IGBTs are illustrated. However, the examples described herein may also be applied to p-channel devices, e.g. p-channel MOSFETs or p-channel IGBTs.

The description and drawings merely illustrate the principles of the disclosure. Furthermore, all examples recited herein are principally intended expressly to be only for illustrative purpose to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

It is to be understood that the disclosure of multiple acts, processes, operations, steps or functions disclosed in the specification or claims may not be construed as to be within the specific order, unless explicitly or implicitly stated otherwise, e.g. by expressions like “thereafter”, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts, -functions, -processes, -operations or -steps, respectively. Such sub acts may be included and part of the disclosure of this single act unless explicitly excluded.

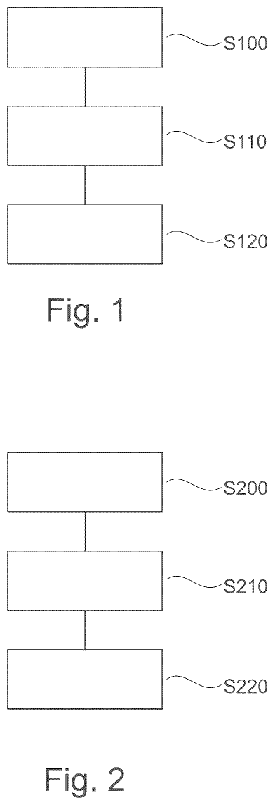

An example of a method of manufacturing a semiconductor device is illustrated by referring to the flowchart of FIG. 1.

Process feature S100 includes forming trench gate structures in a SiC semiconductor body. A mesa is arranged between the trench gate structures.

Process feature S110 includes forming a one-sided channel region in the mesa. The one-sided channel region adjoins a first mesa sidewall of opposite first and second mesa sidewalls.

Process feature S120 includes forming a first region of a first conductivity type in the mesa. The first region adjoins the first mesa sidewall and a top surface of the mesa. Process feature S120 further includes forming a second region of a second conductivity type in the mesa. The second region adjoins the second mesa sidewall and the top surface of the mesa. The first region and the second region are separated by a pn junction at the top surface of the mesa. A width of the first region at the top surface of the mesa may alternate, along a longitudinal direction of the mesa, between a first width range and a second width range. The first width range may be larger than 10% of a width of the mesa at the top surface and may be smaller than 50% of the width of the mesa at the top surface. The second width range may be larger than or equal to 50% of the width of the mesa at the top surface and smaller than 90% of the width of the mesa at the top surface.

A further example of a method of manufacturing a semiconductor device is illustrated by referring to the flowchart of FIG. 2.

Process feature S200 includes forming trench gate structures in a SiC semiconductor body. A mesa is arranged between the trench gate structures.

Process feature S210 includes forming a one-sided channel region in the mesa. The one-sided channel region adjoins a first mesa sidewall of opposite first and second mesa sidewalls.

Process feature S220 includes forming first transverse regions of a first conductivity type adjoining the top surface of the mesa. The first transverse regions may extend from the first mesa sidewall to the second mesa sidewall. Process feature S220 further includes forming second transverse regions of a second conductivity type adjoining to the top surface of the mesa. The second transverse regions may extend from the first mesa sidewall to the second mesa sidewall. The first transverse regions and the second transverse regions may be alternately arranged along a longitudinal direction of the mesa.

The process features may include sub-processes. For example, forming trench gate structures may include, inter alia, sub-processes of forming gate trenches, or forming a trench gate dielectric, or forming a gate trench electrode. For example, some or all sub-processes of a process feature described herein may be carried out before or after sub-processes of another process feature described herein. For example, forming part of the continuous region described herein may be carried out after forming the gate trenches and before forming the trench gate electrode.

For example, forming the trench gate structures may include forming gate trenches in the SiC semiconductor substrate by a masked etch process, i.e. a dry etch process using an etch mask such as, for example, a hard mask. Forming the trench gate structures may further include forming a trench gate dielectric in the trench. For example, directly before the trench gate dielectric formation, one or more cleaning processes for surface conditioning may be carried out. The trench gate dielectric may be formed by or may include an oxidation process, e.g. thermal oxidation process and/or oxide deposition process. Other dielectric materials may be used in addition to or as an alternative to the oxide. For example, high-k materials may be used. For example, the trench gate dielectric layer may include a high-k dielectric layer including at least one of Al₂O₃, ZrO₂, HfO₂, AlN, alumosilicate AlSiOx, silicon La- or Si-doped HfO₂, TiO₂, Y₂O₃, or Si₃N₄. For example, the trench gate dielectric may include at least a first dielectric sub-layer and a second dielectric sub-layer. The first dielectric sub-layer adjoining to a channel region may have a dielectric constant that is smaller than the dielectric constant of the high-k dielectric sub-layer, e.g. be equal to or larger than the dielectric constant of SiO₂. For example, the first dielectric layer may include at least one of SiO₂, AlN, or Si₃N₄, for example. Forming the trench gate trench gate structure that may also include forming a trench gate electrode. The trench gate electrode may include one or more conductive material(s), e.g. metal, metal alloys, e.g. Cu, Au, AlCu, Ag, or alloys thereof, metal compounds, e.g. TiN, highly doped semiconductor material such as highly doped polycrystalline silicon. The one or more conductive materials may form a layer stack, for example. The trench gate electrode may be electrically connected to a gate pad via a gate interconnection structure such as a gate runner, for example. The gate pad/interconnection structure and, for example, a first load electrode pad, e.g. a source pad of a MOSFET or an emitter pad of an IGBT, may be part of a wiring area over the SiC semiconductor body. Forming the wiring area may include forming one or more than one, e.g. two, three, four or even more wiring levels. Each wiring level may be formed by a single one or a stack of conductive layers, e.g. metal layer(s). The wiring levels may be lithographically patterned, for example. Between stacked wiring levels, an interlayer dielectric structure may be arranged. Contact plug(s) and/or contact line(s) may be formed in openings of the interlayer dielectric structure to electrically connect parts, e.g. metal lines or contact areas, of different wiring levels to one another.

The one-sided channel region in the mesa in the mesa may be formed as part of a body region adjoining the first mesa sidewall. For example, the body region may be formed by ion implantation before forming the gate trench structures, e.g. by ion implantation that is unmasked with respect to at least the transistor cell area.

For example, each of the first and second regions may be formed by ion implantation, for example. The first and second regions may be adjusted to one another by an ion implantation mask pattern, e.g. a hard mask, defined by photolithography. For example, dopants of the first and/or second regions may be introduced into the SiC semiconductor body by ion implantation using the ion implantation mask. Similar to the first and second regions, the first transverse regions and second transverse regions may be formed by ion implantation, for example. The first and second transverse regions may be adjusted to one another by an ion implantation mask pattern, e.g. a hard mask, defined by photolithography. For example, dopants of the first and/or second transverse regions may be introduced into the SiC semiconductor body by ion implantation using the ion implantation mask.

For example, the method may further include forming a buried interconnection region of the first conductivity type. The buried interconnection region may extend along the longitudinal direction and electrically connect the first transverse regions with one another. For example, the buried interconnection region may adjoin a bottom side of the second transverse regions. The buried interconnection region may allow for reducing the path resistance of a channel current from the one-sided channel region to the contact on the top surface of the mesa, for example. For example, the buried interconnection region may allow an electron current to flow directly and with low resistance from the first transverse region under the second transverse region into the channel region, thereby extending the electrically active channel width along the entire longitudinal direction, in particular, below the second transverse regions. This may particularly help to reduce the path resistance in those regions where the contact region has a larger width. In those regions where the source contact is wider, the n-buried regions will actually increase the path resistance. In sum, the total path resistance can be reduced.

For example, forming the buried interconnection region may include introducing dopants of the first conductivity type into the SiC semiconductor body by ion implantation through a sidewall of a gate trench, or through a top surface of the SiC semiconductor body before forming the gate trench.

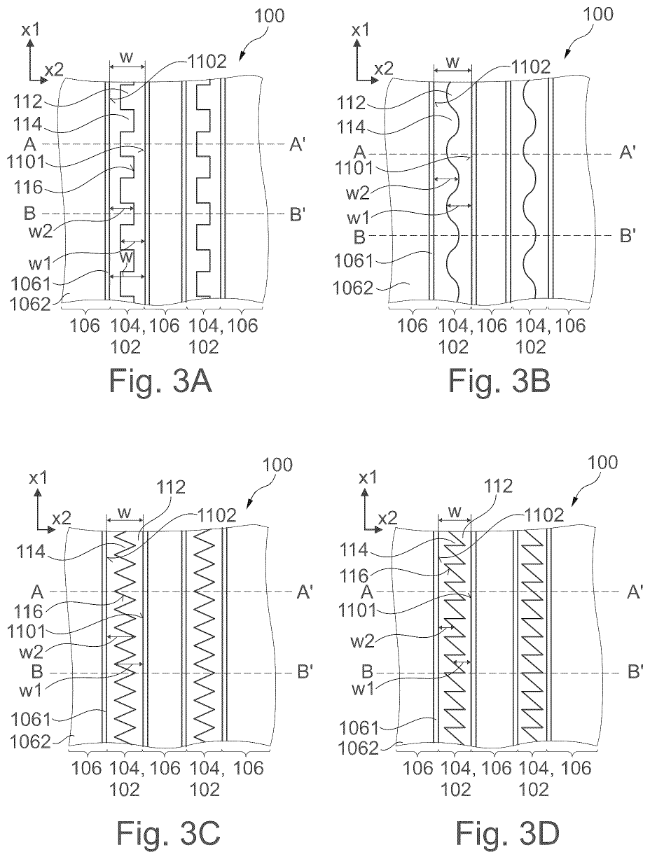

The schematic top views of FIGS. 3A to 3D illustrate configuration examples of semiconductor devices 100 including a mesa 104 in a SiC semiconductor body 102. The mesa 104 is laterally confined by trench gate structures 106. Each of the trench gate structures 106 includes a trench gate dielectric 1061 and a trench gate electrode 1062.

Each of the mesas 104 illustrated in FIGS. 3A to 3D includes an n⁺-doped first region 112, e.g. a source region, adjoining a first mesa sidewall 1101. The mesa 104 further includes a p⁺-doped second region 114, e.g. a contact region, adjoining a second mesa sidewall 1102. A pn junction 116 laterally separates the first region 112 from the second region 114.

The configuration examples of FIGS. 3A to 3D differ with respect to a layout of the first and second regions 112, 114 at a top surface of the mesa 104. In the views on the top surface of the mesa 104 of FIGS. 3A to 3D, a shape of the first region 112 along a longitudinal direction x1 is a square wave in FIG. 3A, or a sine wave in FIG. 3B, or a triangle wave in FIG. 3C, or a sawtooth wave in FIG. 3D.

The layouts in FIGS. 3A to 3D have in common that a width w1 of the first region 112 at the top surface of the mesa 104 alternates, along the longitudinal direction x1 of the mesa 104, between a first width range and a second width range. The first width range is larger than 10% of a width w of the mesa 104 at the top surface and smaller than 50% of the width w of the mesa 104 at the top surface. The second width range is larger than or equal to 50% of the width w of the mesa 104 at the top surface and smaller than 90% of the width w of the mesa 104 at the top surface. Likewise, a width w2 of the second region 114 at the top surface of the mesa 104 alternates, along the longitudinal direction x1 of the mesa 104, between a first width range and a second width range. The first width range is larger than 10% of a width w of the mesa 104 at the top surface and smaller than 50% of the width w of the mesa 104 at the top surface. The second width range is larger than or equal to 50% of the width w of the mesa 104 at the top surface and smaller than 90% of the width w of the mesa 104 at the top surface.

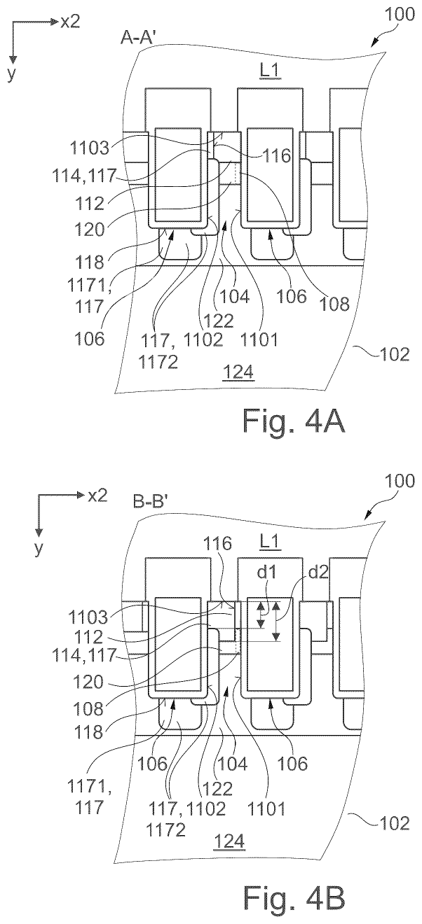

FIG. 4A schematically and exemplarily shows a partial cross-sectional view of the semiconductor device 100 view along line AA′ of any of FIGS. 3A to 3D. FIG. 4B schematically and exemplarily shows a partial cross-sectional of the semiconductor device 100 view along line BB′ of any of FIGS. 3A to 3D. The n⁺-doped first region 112 is a source region and the p⁺-doped second region 114 is a contact region.

Referring to FIGS. 4A and/or 4B, the semiconductor device 100 may be a vertical power semiconductor device that further includes an edge termination area that at least partially surrounds the active area (not illustrated in FIGS. 4A, 4B). The semiconductor device 100 includes the mesa 104 having a top surface 1103. The mesa 104 is confined by the trench gate structures 106 along a second lateral direction x2. The second lateral direction x2 is perpendicular to the longitudinal direction x1.

As is illustrated in FIG. 4B, a first depth d1 from a bottom side of the contact region 114 to the top surface 1103 of the mesa 104 is larger than a second depth d2 from a bottom side of the source region 112 to the top surface 1103 of the mesa 104.

The second region 114 is part of a p-doped continuous region 117. The continuous region 117 adjoins the second mesa sidewall 1102 and a bottom side 118 of trench gate structures 106.

The continuous region 117 completely covers the second sidewall 1102 from the bottom side 118 of the trench gate structures 106 to the top surface 1103 of the mesa 104. A vertical doping concentration profile of the continuous region 117 may include a plurality of doping concentration profiles of p-doped sub-region regions that partially overlap along a vertical direction y, for example a bottom portion 1171 adjoining the bottom side 118 of the trench gate structures 106, a middle portion 1172 adjoining the second mesa sidewall 1102, and the contact region 114. A p-doped body region 120 is arranged between the continuous region 117 and the first mesa sidewall 1101 along the second lateral direction x2. A one-sided channel region 108 is defined by a part of the body region 120 that adjoining the first mesa sidewall. For example, the one-sided channel region 108 may be defined by that part of the body region 120 where inversion can be induced by field effect when applying a turn-on voltage to the trench gate electrode 1102, for example.

The semiconductor device 100 further includes an n-doped current spread region 122 between the body region 120 and an n-doped drift region 124. The n-doped current spread region adjoins the one-sided channel region 108 and may have a larger doping concentration that the n-doped drift region 124. For semiconductor devices based on a SiC semiconductor substrate, a mean impurity concentration in the drift region 124 may be between 5×10¹⁴ cm⁻³ and 1×10¹⁷ cm⁻³, for example in a range from 1×10¹⁵ cm⁻³ to 2×10¹⁶ cm⁻³, for example. A vertical extent of the drift region 124 may depend on voltage blocking requirements, e.g. a specified voltage class, of the semiconductor device 100. When operating the semiconductor device 100 in voltage blocking mode, a space charge region may vertically extend partly or totally through the drift region 124 depending on the blocking voltage applied to the SiC semiconductor device. When operating the semiconductor device at or close to the specified maximum blocking voltage, the space charge region may reach or extend into a buffer region that is configured to prevent the space charge region from further reaching to a contact of a second load electrode at a second surface of the SiC semiconductor body 102.

A first load electrode L1, e.g. a source or emitter electrode, is arranged over the mesa 104, and is electrically connected to the first or source region 112 and the second or contact region 114 via the top surface 1103 of the mesa 104. In view of the layout of the first and second regions 112, 114 at the top surface 1103 of the mesa (see. e.g. FIGS. 3A to 3D), a contact surface coverage on the top surface 1103 of the mesa 104 by the second or contact region 114 (likewise by the first or source region 112) varies along the longitudinal direction x1.

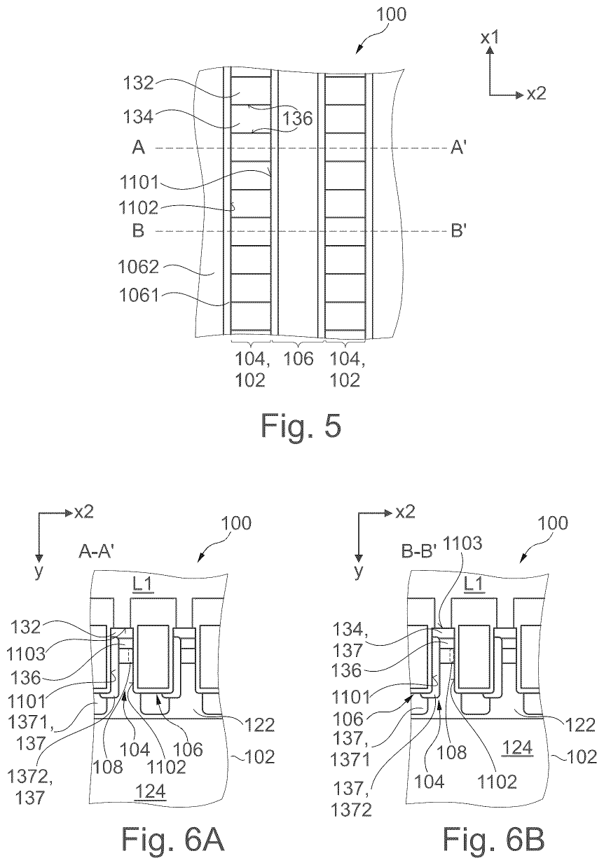

The schematic top view of FIG. 5 illustrates a further configuration example of a semiconductor devices 100 including a mesa 104 in a SiC semiconductor body 102. The mesa 104 is laterally confined by trench gate structures 106. Each of the trench gate structures 106 includes a trench gate dielectric 1061 and a trench gate electrode 1062.

Each of the mesas 104 illustrated in FIG. 5 includes n⁺-doped first transverse regions 132, e.g. source regions. The first transverse regions 132 extend from the first mesa sidewall 1101 to the second mesa sidewall 1102. The mesa 104 further includes p⁺-doped second transverse regions 134, e.g. contact regions. The second transverse regions 134 extend from the first mesa sidewall 1101 to the second mesa sidewall 1102. The first and second transverse regions 132, 134 are alternately arranged along the longitudinal direction x1 and separated by pn junctions 138.

FIG. 6A schematically and exemplarily shows a partial cross-sectional view of the semiconductor device 100 view along line AA′ of FIG. 5. FIG. 6B schematically and exemplarily shows a partial cross-sectional of the semiconductor device 100 view along line BB′ of FIG. 5. The n⁺-doped first transverse regions 112 are source regions and the p⁺-doped second transverse regions are contact regions.

Referring to FIGS. 6A and/or 6B, the semiconductor device 100 includes the mesa 104 having a top surface 1103. The mesa 104 is confined by the trench gate structures 106 along a second lateral direction x2 that is opposite to the longitudinal or first direction x1.

The second transverse regions 134 are part of a p-doped continuous region 137. The continuous region 137 adjoins the second mesa sidewall 1102 and a bottom side 118 of trench gate structures 106. The continuous region 137 completely covers the second sidewall from the bottom side 118 of the trench gate structures 106 to the top surface 1103 of the mesa 104 at positions along the longitudinal direction x1 where the second transverse or contact regions 134 are arranged. A vertical doping concentration profile of the continuous region 137 may include a plurality of doping concentration profiles of p-doped sub-regions that partially overlap along the vertical direction y, for example a bottom portion 1371 adjoining the bottom side 118 of the trench gate structures 106, a middle portion 1372 adjoining the second mesa sidewall 1102, and the second transverse region or contact region 134. A p-doped body region 120 is arranged between the continuous region 137 and the first mesa sidewall 1101 along the second lateral direction x2. A one-sided channel region 108 is defined by a part of the body region 120 that adjoins the first mesa sidewall 1101.

The semiconductor device 100 further includes an n-doped buried interconnection region 136. The buried interconnection region 136 extends along the longitudinal direction x1 and electrically connects the first transverse regions 132 to one another. For example, the buried interconnection region 136 may adjoin a bottom side of the second transverse or contact regions 134 and may also adjoin a bottom side of the first transverse or source regions 132 for providing the electric interconnection. For example, a maximum doping concentration of the first transverse regions 132 is by at least one order of magnitude larger than a maximum doping concentration of the buried interconnection region 136. The buried interconnection region 136 may also be used in the configuration examples illustrated in FIGS. 3A to 4B, for example.

The semiconductor device 100 further includes an n-doped current spread region 122 between the body region 120 and an n-doped drift region 124. The n-doped current spread region 122 adjoins the one-sided channel region 108.

A first load electrode L1, e.g. a source or emitter electrode, is arranged over the mesa 104, and is electrically connected to the first transverse or source region 132 and the second transverse or contact region 134 via the top surface 1103 of the mesa 104, e.g. as a line shape-contact extending along the longitudinal direction x1. In view of the layout of the first and second transverse regions 132, 134 at the top surface 1103 of the mesa (see. e.g. FIGS. 3A to 3D), a contact surface of a line-shape contact on the top surface 1103 of the mesa 104 alternates between contacting the first and second transverse regions 132, 134 along the longitudinal direction x1.

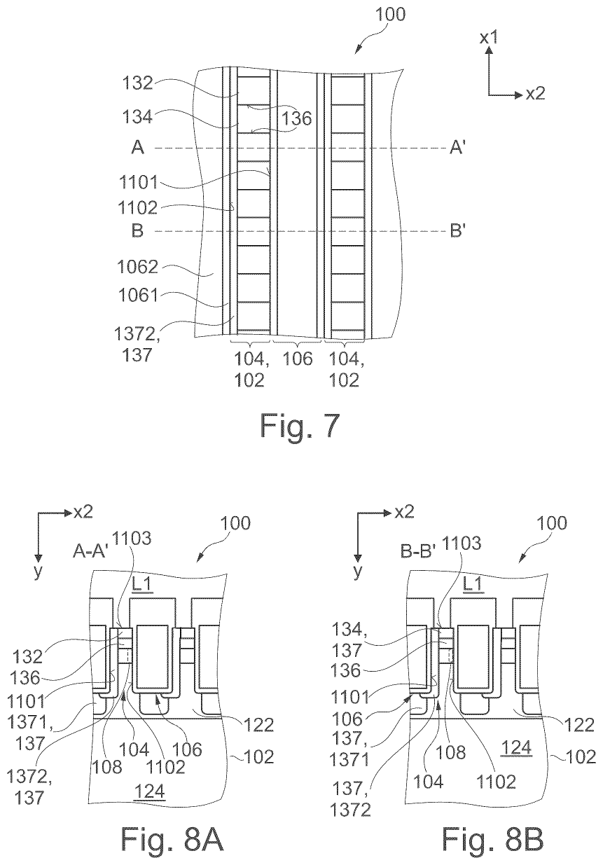

The schematic top view of FIG. 7 and the related cross-sectional views of FIGS. 8A and 8B schematically and exemplarily illustrate a further configuration example of a semiconductor device 100 that is based on the example illustrated in FIGS. 5, 6A, 6B. Other than in the example illustrated in FIGS. 5, 6A, 6B, the example illustrated in FIGS. 7, 8A, 8B has a middle portion 1372 of the continuous region 137 that extends up to the top surface 1103 of the mesa 104. The middle portion 1372 of the continuous region 137 may have a larger doping concentration at the top surface 1103 than each of the first and second transverse regions 132, 134, for example.

The aspects and features mentioned and described together with one or more of the previously described examples and figures, may as well be combined with one or more of the other examples in order to replace a like feature of the other example or in order to additionally introduce the feature to the other example.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a SiC semiconductor body comprising a mesa between trench gate structures, wherein the mesa includes:
a one-sided channel region adjoining a first mesa sidewall of opposite first and second mesa sidewalls;
a first region of a first conductivity type adjoining the first mesa sidewall and a top surface of the mesa;
a second region of a second conductivity type adjoining the second mesa sidewall and the top surface of the mesa,
wherein the first region and the second region are separated by a pn junction at the top surface of the mesa,
wherein a width of the first region at the top surface of the mesa alternates, along a longitudinal direction of the mesa, between a first width range and a second width range,
wherein the first width range is larger than 10% of a width of the mesa at the top surface and smaller than 50% of the width of the mesa at the top surface, and
wherein the second width range is larger than or equal to 50% of the width of the mesa at the top surface and smaller than 90% of the width of the mesa at the top surface.

2. The semiconductor device of claim 1, wherein the first region is a source region, wherein the second region is a contact region, and wherein a first depth from a bottom side of the contact region to the top surface of the mesa is larger than a second depth from a bottom side of the source region to the top surface of the mesa.

3. The semiconductor device of claim 1, wherein the second region is part of a continuous region of the second conductivity type, and wherein the continuous region adjoins the second mesa sidewall and a bottom side of a trench gate structure.

4. The semiconductor device of claim 3, wherein the continuous region completely covers the second sidewall from the bottom side of the trench gate structure to the top surface of the mesa.

5. The semiconductor device of claim 3, further comprising:
a body region of the second conductivity type laterally arranged between the continuous region and the first mesa sidewall.

6. The semiconductor device of claim 1, further comprising:
a buried third region of the first conductivity type adjoining a bottom side of the first region.

7. The semiconductor device of claim 1, wherein a maximum doping concentration of the first region is by at least one order of magnitude larger than a maximum doping concentration of the buried third region.

8. The semiconductor device of claim 1, wherein in a top view on the top surface of the mesa, a shape of the first region along the longitudinal direction is at least one of a sine wave, or a square wave, or a triangle wave, or a sawtooth wave.

9. The semiconductor device of claim 1, wherein the first region is an n⁺⁺-doped source region, and wherein a surface coverage of the top surface of the mesa by the second region is by more than 10% larger than a surface coverage of the top surface of the mesa by the first region.

10. The semiconductor device of claim 1, wherein the first region is an n⁺⁺-doped source region, and wherein a surface coverage of the top surface of the mesa by the second region is equal to a surface coverage of the top surface of the mesa by the first region.

11. A semiconductor device, comprising:
a SiC semiconductor body comprising a mesa between trench gate structures, wherein the mesa includes:
a one-sided channel region adjoining a first mesa sidewall of opposite first and second mesa sidewalls;
a plurality of first transverse regions of a first conductivity type adjoining the top surface of the mesa, and extending from the first mesa sidewall to the second mesa sidewall; and
a plurality of second transverse regions of a second conductivity type adjoining the top surface of the mesa and extending from the first mesa sidewall to the second mesa sidewall,
wherein the first transverse regions and the second transverse regions are alternately arranged along a longitudinal direction of the mesa.

12. The semiconductor device of claim 11, further comprising:
a buried interconnection region of the first conductivity type,
wherein the buried interconnection region extends along the longitudinal direction and electrically connects the first transverse regions with one another.

13. The semiconductor device of claim 12, wherein a maximum doping concentration of the first transverse regions is by at least one order of magnitude larger than a maximum doping concentration of the buried interconnection region.

14. The semiconductor device of claim 11, wherein the second transverse regions are part of a continuous region of the second conductivity type, and wherein the continuous region adjoins the second mesa sidewall and a bottom side of a trench gate structure.

15. The semiconductor device of claim 11, further comprising:
a line-shape contact on the top surface of the mesa, the line shape-contact extending along the longitudinal direction.

16. A method of manufacturing a semiconductor device, the method comprising:
forming a plurality of trench gate structures in a SiC semiconductor body, wherein a mesa is arranged between the trench gate structures;
forming a one-sided channel region in the mesa, the one-sided channel region adjoining a first mesa sidewall of opposite first and second mesa sidewalls;
forming a first region of a first conductivity type in the mesa, the first region adjoining the first mesa sidewall and a top surface of the mesa;
forming a second region of a second conductivity type in the mesa, the second region adjoining the second mesa sidewall and the top surface of the mesa, wherein the first region and the second region are separated by a pn junction at the top surface of the mesa,
wherein a width of the first region at the top surface of the mesa alternates, along a longitudinal direction of the mesa, between a first width range and a second width range,
wherein the first width range is larger than 10% of a width of the mesa at the top surface and smaller than 50% of the width of the mesa at the top surface, and
wherein the second width range is larger than or equal to 50% of the width of the mesa at the top surface and smaller than 90% of the width of the mesa at the top surface.

17. A method of manufacturing a semiconductor device, the method comprising:
forming a plurality of trench gate structures in a SiC semiconductor body, wherein a mesa is arranged between adjacent ones of the trench gate structures;
forming a one-sided channel region in the mesa, the one-sided channel region adjoining a first mesa sidewall of opposite first and second mesa sidewalls;
forming a plurality of first transverse regions of a first conductivity type adjoining to the top surface of the mesa, and extending from the first mesa sidewall to the second mesa sidewall; and
forming a plurality of second transverse regions of a second conductivity type adjoining the top surface of the mesa, and extending from the first mesa sidewall to the second mesa sidewall,
wherein the first transverse regions and the second transverse regions are alternately arranged along a longitudinal direction of the mesa.

18. The method of claim 17, further comprising:
forming a buried interconnection region of the first conductivity type,
wherein the buried interconnection region extends along the longitudinal direction and electrically connects the first transverse regions with one another.

19. The method of claim 18, wherein forming the buried interconnection region comprises:
introducing dopants of the first conductivity type into the SiC semiconductor body by ion implantation through a sidewall of a gate trench, or through a top surface of the SiC semiconductor body before forming the gate trench.
